(19) United States
(12) Patent Application Publication
(10) Pub. No.: US 2009/0040074 A1
(43) Pub. Date: Feb. 12, 2009

(54) Configurable keypad

(75) Inventors: Melissa A. McTavish, Peoria, IL (US); David A. Hale, Chillicothe, IL (US)

Correspondence Address: Caterpillar Inc.;Intellectual Property Dept., AH 9510, 100 N.E. Adams Street, PEORIA, IL, 61629-9510, US

(73) Assignee: Caterpillar Inc.

(21) Appl. No.: 11/890,632

(22) Filed: Aug. 7, 2007

(51) Int. Cl. H03K 17/94

(52) U.S. Cl. 341/22

(57) ABSTRACT

A configurable keypad for a machine. The keypad may include a plurality of pushbuttons having selectively illuminated icons and indicator lights identifying available operations on the machine. A controller may determine when the machine is authorized to perform a particular operation. The controller may then enable select pushbuttons and illuminate associated icons and indicator lights. The icons and indicator lights may be selectively translucent such only illuminated icons and indicator lights may be visible to a machine operator.

### TECHNICAL FIELD

The present invention relates generally to a configurable keypad, and more particularly to indicating available machine operations on the keypad.

### BACKGROUND

Machines may be configured to perform a variety of operations and typically use keypads to select various operations by depressing various pushbuttons on the keypad. These same machines may also be sold with different configurations to perform different operations or tasks that also require selecting a pushbutton on a keypad to cause a specific operation. Furthermore, these machines may have a variety of tools that may be attachable to the machine to perform even more tasks. Each tool may have a new set of available operations that may require additional pushbuttons to enable the operation and may make pushbuttons associated with previous attachment and operations obsolete.

Keypads are well known in the art for identifying a particular pushbutton of the keypad with a particular operation of a machine. However, as machines are customized with different configurations and different attachments are added to the machine as discussed above, additional keypads may be required, or the number of pushbuttons per keypad may begin to significantly increase. Ultimately, this leads to increased cost and increased complexity of the systems.

In U.S. Patent Application 2006/0022053, a system and method is disclosed for facilitating configuration of a keypad by mapping individual functions of the keypad to characters or functions predefined by the user that may be unique to that user. However, this disclosure may lead to extra work each time an attachment is changed on the machine or the machine switches to new operation modes. Specific keys of the keypad may require reprogramming each time this happens. Alternatively, if there are enough buttons to be programmed to account for all the different operating modes with different configurations and attachments, the keypad may become exceedingly confusing to identify which pushbuttons are active per mode.

It is desirable to provide a keypad with pushbuttons that are configurable for potentially available operations and are identified when those operations are actually available to perform.

### SUMMARY OF THE INVENTION

It is to be understood that both the foregoing general description and the following detailed description are exemplary and explanatory only and are not restrictive of the invention as claimed.

One aspect of the present invention is directed to a configurable operator control station for a machine. This operator control station may comprise a keypad and a controller. The keypad may have a plurality of pushbuttons. Each pushbutton may have an indicator portion identifying an operation of the machine. The controller may be configured to determine when the machine is authorized to perform the particular operation. The indicator portion may be illuminated when the machine is authorized to perform the operation.

Another aspect of the present invention is directed to a method for selective operation of a keypad for a machine. The method may comprise associating a pushbutton of the keypad with an operation of the machine, determining if the machine is authorized to perform the operation, and illuminating a select portion of the pushbutton in response to authorization.

Another aspect of the present invention is directed to a configurable keypad for a machine. The keypad may comprise a plurality of pushbuttons. Each pushbutton may have an indicator portion identifying an operation of the machine and a means for receiving an a machine authorization signal. The indicator portion may be illuminated in response to receiving the machine authorization signal.

### BRIEF DESCRIPTION OF THE DRAWINGS

The accompanying drawings, which are incorporated in and constitute a part of this specification, illustrate several exemplary embodiments of the invention and, together with the description, serve to explain the principles of the invention. In the drawings,

FIG. 1 is a diagrammatic illustration of a machine where one embodiment of the present disclosure may be employed;

FIG. 2 is a perspective view of an operator control station of FIG. 1 according to one embodiment of the present disclosure;

FIG. 3 is a perspective view of a keypad according to one embodiment of the present disclosure;

FIG. 4 is a perspective view of the keypad of FIG. 3 showing active pushbuttons and inactive pushbuttons according to one embodiment of the present disclosure; and

FIG. 5 is a schematic view of a controller and keypad having a plurality of pushbuttons according to one embodiment of the present disclosure.

### DETAILED DESCRIPTION

Reference will now be made in detail to embodiments of the invention, examples of which are illustrated in the accompanying drawings. Whenever possible, the same reference numbers will be used throughout the drawings to refer to the same or like parts.

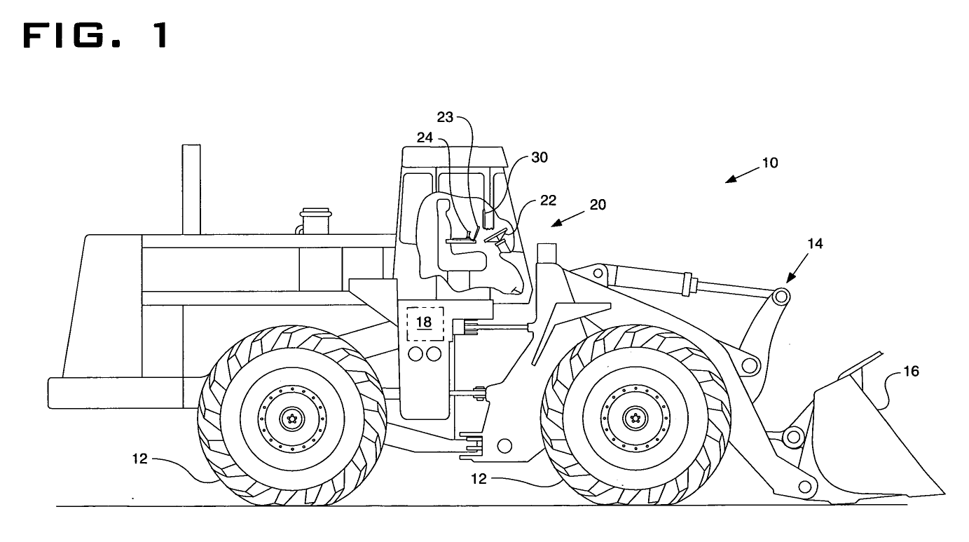

FIG. 1 shows a diagrammatic illustration of a machine 10, such as a wheel loader, where one embodiment of the present disclosure may be employed. The machine 10 may comprise tires 12, lift mechanism 14, implement 16, and operator control station 20. Although the machine 10 is shown as a wheel loader, the machine 10 may be any kind of mobile or stationary machine that generally has a need for operator inputs to enable execution of an operation. For example, mobile machines may include wheel loaders, excavators, track type loaders, dump trucks, garbage trucks, marine propulsion systems, locomotives, trucks, cars, etc. Stationary machines may include power generation systems, machining systems, other manufacturing tools and systems, other logic based machines, etc.

The machine 10 may also include at least one controller 18. The controller 18 preferably includes programming specific to the machine 10. The controller 18 may be microprocessor based, as is known in the art, and may be but one of a number of controllers for controlling different functions and operations of the machine 10.

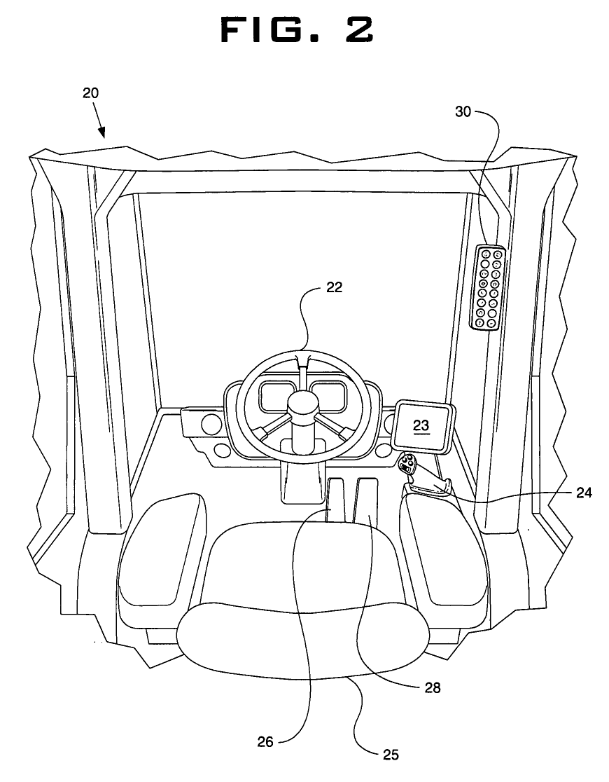

Referring to FIG. 2, there is shown a perspective view of the operator control station 20 of FIG. 1. The operator control station 20 may include and a number of devices, including a steering control device 22, lift control device 24, brake pedal 26, throttle pedal 28, seat 25 and keypad 30. The controller 18 may be configured such that inputs from the operator control station 18, including that from the steering control device 22, lift control device 24 and keypad 30, may affect the operation of many devices associated with the machine 10, as well as their own operation. Devices may include, but are not limited to, the lift mechanism 14, implement 16, interior and exterior lights (not shown), powertrain (not shown), wipers (not shown), horns (not shown), brakes (not shown), alarms (not shown), etc.

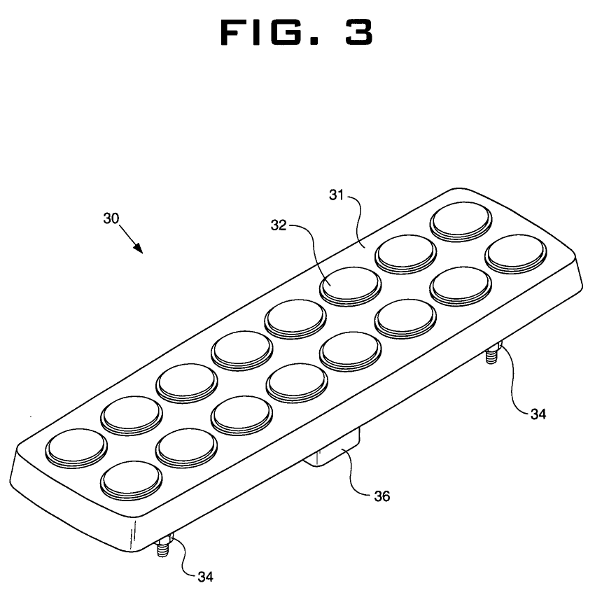

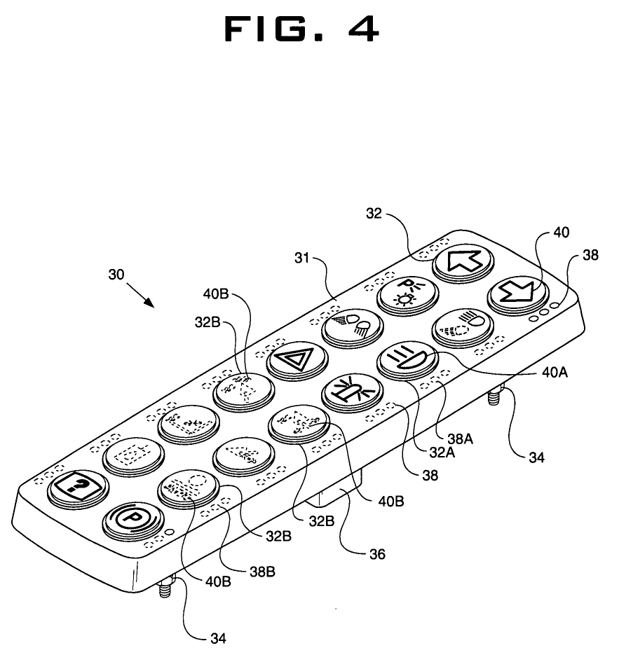

Referring to FIGS. 3 and 4, a perspective view of a keypad 30 is shown according to one embodiment of the present disclosure. The keypad 30 may have a plurality of pushbuttons 32 arranged on the keypad surface 31, mounting hardware 34, and a connector interface 36. Although the keypad 30 is shown mounted in an operator control station 20 and having mounting hardware 34 consisting of studs and nuts, the keypad 30 may be mounted in any number of ways, including using adhesive, screws, mounting brackets, and the like, and in a location accessible to an operator to be able to effectuate an associated operation of the machine 10 at an appropriate time.

Mounting of the keypad 30 on the machine 10 may also cause the connector interface 36 to make electrical contact with a mating connector interface (not shown) on the machine 10. The connector interface 36 may be a 6-pin connector as used in the art, but may make use of any connector arrangement as may be suitable for the task of making electrical connection with the machine 10. Alternatively, the keypad 30 may be directly wired to the machine 10 without any intermediate connector. The keypad 30 may also be configured to communicate with the machine 10 wirelessly using, for example, radio frequency signals and the like.

When the machine 10 is off, the plurality of pushbuttons 32 may appear to be blank, as shown in FIG. 3. Alternatively, as shown in FIG. 4, when the machine 10 is on, icons 40, or an indicator portion of the pushbutton, may appear visible on at least a portion of the pushbuttons 32, at least as compared to the rest of the icons 40. Indicator lights 38 may or may not also appear visible in the keypad surface 31 depending on the operating state of the machine 10. Indicator lights 38 may be a plurality of separate lights associated with a specific icon 40 that represents various machine states or operating conditions. Although the keypad 30 is shown having a total of sixteen pushbuttons 32, the keypad 30 may have more or less pushbuttons 32. Each pushbutton 32 may also have one or more icons 40 and varying numbers of associated indicator lights 38. Alternatively, each pushbutton 32 may not have any icons 40 or associated indicator lights 38.

Pushbuttons 32 may be integrated in the keypad surface 31 and may be removable from the keypad surface 31 such that they are interchangeable or replaceable. Accordingly, it may be necessary that as machine operation and equipment changes, the associated pushbutton 32 would need to be reprogrammed and the icon 40 changed. Although each pushbutton 32 may be raised from the keypad surface 31, the pushbuttons 32 may also be flush or recessed from the keypad surface 31. Furthermore, each pushbutton 32 may be rotatable within the keypad 30 such that each pushbutton 32 is adaptable to the mounting orientation of the keypad 30.

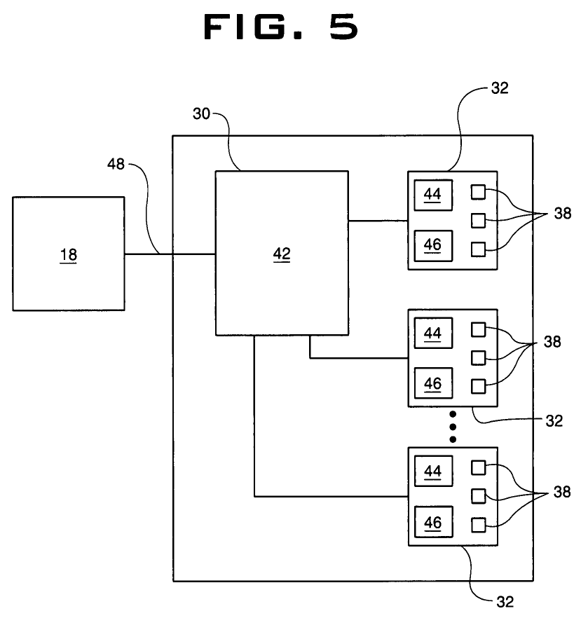

Each pushbutton 32 may be formed separately from a translucent material, such as silicon and the like, or may be formed integral to the keypad surface 31. The icons may be formed in any one of a number of ways as known in the art. In one embodiment, the pushbutton 32 may have a opaque overlay over the silicon, or over a lighter paint, and then etched using techniques such as laser etching and the like to form the icon 40 or plurality of icons 40 on the pushbutton 32. In a second embodiment, the silicon may be painted with an opaque overlay to form the icon 40. Additionally, the keypad surface 31 may be etched such that a portion of the keypad surface 31 may appear as indicator lights 38. Each pushbutton 32 may then have a translucent paint overlay applied to the icon 40 and indicator light 38 such that they are selectively translucent, or may only be visible when a backlight 46 (shown in FIG. 5) is turned on.

FIG. 5 is a schematic view of the controller 18 and keypad 30 having a plurality of pushbuttons 32 according to one embodiment of the present disclosure. Each pushbutton 32 may have a switch 44, a backlight 46 and at least one indicator light 38. Each pushbutton 32 may be wired to the microprocessor 42. The microprocessor 42 may be connected to the controller 18 over a data link 48.

Switch 44 may be any type of switch known in the art, such as a dome switch and the like, but may also be a sensor, and the like as suitable for the application. Each switch 44 may be programmed to cause a particular machine function to occur and may be represented by the icon 40 on the pushbutton 32. As options on the machine are changed, the switch 44 may be reprogrammed to cause different machine functions to occur. Similarly, the backlight 46 and indicator lights 38 may be programmed to represent various operating conditions of the associated machine function. As the switch 44 is reprogrammed, it may be necessary to replace the keypad or just the pushbutton 32 such that a new icon 40 properly represents the new machine function.

The backlight 46 and indicator lights 38 may consist of a light emitting diode (LED) or another similar light source that is bright enough for a machine operator to see the icon 40 and indicator lights 38 in varying environments. It may also be necessary to take measures to prevent the backlight 46 from one icon 40 to be visible in an adjacent icon 40 and from one indicator light 38 to an adjacent indicator light 38. The backlight 46 may also have varying degrees of operation such that in a first embodiment the backlight 46 is off, in a second embodiment the backlight 46 is dim, and in a third embodiment the backlight 46 is bright. Alternatively, the backlight 46 may be infinitely variable from fully off to fully on such that the brightness of the icon 40 may be selectable or user settable. The backlight 46 may be the same or different colors as may be required by various international regulations. The different colors may also be visible through the icons 40 and may represent different operating conditions of the machine 10. Furthermore, the indicator lights 38 associated with an icon 40 may be the same or different colors and have varying brightness to indicate various stages of operation of the machine 10 associated with the icon 40.

As the pushbutton 32 is selected, contact may be made between the pushbutton 32 and a switch 44. The switch 44 may cause a signal to be created and sent over a signal wire to a microprocessor 42 contained within the keypad 30. Upon receipt of the signal from the pushbutton 32, the microprocessor 42 may be configured to create a message using a machine messaging protocol, such as a controller area network, or CAN, message that may be sent over a data link 48 to the controller 18 requesting operation of a certain action of the machine 10. The controller 18 may then cause the requested operation to occur on the machine 10.

The microprocessor 42 may also be configured to receive a CAN message from the controller 18 over the data link 48. The message from the controller 18 may indicate to the microprocessor 42 the status of the machine 10 and what operations the machine 10 is capable of performing. Accordingly, the microprocessor 42 may cause the backlights 46 and/or the indicator lights 38 to turn on or turn off such that the machine operator knows that an operation indicated by an associated icon 40 is available and/or the status of the indicated operation. It is contemplated that the indicator lights 38 and backlights 46 may be illuminated upon selecting the pushbutton 32 or only upon confirmation from the controller 18 that the requested operation occurred. The controller 18 may also lock out pushbuttons 32 with icons turned off such that pressing them will not cause the associated operation on the machine 10. It is also contemplated that the keypad may have distributed processing among the pushbuttons, such that each pushbutton 32 is able to send and receive CAN messages over the data link 48 to and from the controller 18.

### INDUSTRIAL APPLICABILITY

Embodiments of the present application are applicable to provide a configurable keypad 30 where it is important for a machine operator to be notified of only the available and authorized operations of the machine 10.

Each pushbutton 32, and associated icon 40, on the keypad 30 may represent a separate machine function. For example, as shown in FIG. 4, the icons 40 may represent various machine operations, such as left and right hazards, parking brakes lights, dome lights, high beams or low beams, front and rear work lights, high intensity worklights, blinking hazards, rotating warning beacon, bucket kickout, bucket raise and lower setpoints, fork kickout, work tool select, implement lockout, ride control, application assistance, and parking brake. Indicator lights 38 may represent various operating states of the machine associated with each machine operation, such as the ones above.

As the machine 10 is started, the controller 18 may determine the operating state of the machine 10 and which pushbuttons 32 should be active and have illuminated icons 40 and indicator lights 38. The controller 18 may determine that the machine 10 is in park and which lights may currently be on and others that are available to turn on. Subsequently, the controller 18 may send a CAN message to the microprocessor 42 requesting that certain pushbuttons 32 be made active, or enabled, and associated icons 40 and indicator lights 38 be illuminated. The operator may take notice of the illuminated icons 40 and indicator lights 38 associated with the machine 10 being in park and lights that are currently on and determine which additional pushbuttons 32 need to be selected to start work with the machine 10. For example, the operator may depress the pushbutton 32 associated with the high intensity work lights icon 40A. The switch 44 may then be engaged, causing a signal to be sent to the microprocessor 42 to create a CAN message for the controller 18. The controller 18 may create another CAN message, or send a signal, to the high intensity worklights (not shown) turning them on to a first operating state. The controller 18 may receive a signal or message back from the worklights confirming that they came on and create another CAN message for the microprocessor 42. The microprocessor 42 may then send a signal to one of the indicator lights 38A for the pushbutton 32A to indicate that the worklight is on.

As the operator takes the machine 10 out of park and into gear, the controller 18 may determine a change in operating state of the machine 10 and send a CAN message to the microprocessor 42 indicating the updated and allowed machine operations. Accordingly, the controller 18 may send at least one CAN message to the microprocessor 42 requesting that pushbuttons 32B for bucket kickout, bucket raise and lower setpoints, and ride control be made active and the associated icons 40B be illuminated. If the operator selects any of these pushbuttons 32B, then the indicator lights 38B may be illuminated to identify the operating state of that machine operation or indicate that the machine feature is active. As additional changes are made in the operating state of the machine 10, the available operations, as identified on the keypad 30, will be updated by the controller 18.

It will be apparent to those skilled in the art that various modifications and variations can be made in the system and method of the present invention without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims and their equivalents.

What is claimed is:

1. A configurable operator control station for a machine, comprising:
a keypad having a plurality of pushbuttons, at least one pushbutton having an indicator portion identifying an operation of the machine; and
a controller configured to determine when the machine is authorized to perform the particular operation;
wherein the indicator portion is illuminated when the machine is authorized to perform the particular operation.

2. The operator control station of claim 1, further including:
at least one indicator light associated with the at least one pushbutton;
wherein the at least one indicator light is illuminated to identify an operating state of the machine relating to the associated pushbutton.

3. The operator control station of claim 2, wherein illumination of at least one of the indicator portion and the indicator lights is operable to change as the operating state of the machine changes.

4. The operator control station of claim 1, wherein illumination of the indicator portion is operable to change as an operating state of the machine changes.

5. The operator control station of claim 1, wherein the controller detects an operating state of the machine to determine authorization of each pushbutton.

6. The operator control station of claim 1, wherein each pushbutton is operable to cause the operation of the machine identified by the indicator portion.

7. The operator control station of claim 1, wherein each pushbutton is operable to cause the particular operation when the indicator portion is illuminated.

8. The operator control station of claim 1, wherein the indicator portion is turned off when the machine is unauthorized to perform the particular operation.

9. The operator control station of claim 7, wherein the pushbutton is unable to cause the particular operation when the indicator portion is not illuminated.

10. The operator control station of claim 1, wherein the controller is further configured to determine the illumination of the indicator portion.

11. The operator control station of claim 1, wherein the indicator portion is selectively translucent.

12. A method for selective operation of a keypad for a machine, comprising
associating a pushbutton of the keypad with an operation of the machine;
determining if the machine is authorized to perform the operation; and
illuminating a select portion of the pushbutton in response to authorization.

13. The method of claims 12, further including:
associating at least one an indicator light with the pushbutton; and
illuminating the at least one indicator light in response to the machine performing the operation.

14. The method of claim 13, further including:
changing the illumination of at least one of the select portion of the pushbutton and the indicator light in response to a change in an operating state of the machine.

15. The method of claim 12, further including:
changing the illumination of the select portion of the pushbutton in response to a change in an operating state of the machine.

16. The method of claim 12, wherein determining if the machine is authorized to perform the operation further includes:
detecting an operating state of the machine.

17. The method of claim 12, further including:
enabling the pushbutton to cause the operation upon determining that the machine is authorized to perform the operation.

18. The method as set forth in claim 12, further including:
disabling the pushbutton and turning off the select portion of the pushbutton in response to determining that the machine is not authorized to perform the operation.

19. A configurable keypad for a machine, comprising:
a plurality of pushbuttons, each having an indicator portion identifying an operation of the machine; and
means for receiving a machine authorization signal;
wherein the indicator portion is illuminated in response to receiving the machine authorization signal.

20. The configurable keypad of claim 19, further including:
at least one indicator light associated each pushbutton;
wherein the at least one indicator light is illuminated to identify an operating state of the machine relating to the associated pushbutton.
